(19) United States
(12) Patent Application Publication
(10) Pub. No.: US 2026/0312556 A1
(43) Pub. Date: Oct. 8, 2026

(54) SIMULTANEOUS COMMON-MODE AND DIFFERENTIAL MODE OFFSET COMPENSATION IN ANALOG CIRCUITS

(71) Applicant: BAE Systems Information and Electronic Systems Integration Inc., Nashua, NH (US)

(72) Inventor: Gary M. Madison, Waltham, MA (US)

(73) Assignee: BAE Systems Information and Electronic Systems Integration Inc., Nashua, NH (US)

(21) Appl. No.: 19/170,246

(22) Filed: Apr. 4, 2025

(51) Int. Cl. H03F 3/45

(52) U.S. Cl. CPC H03F 3/45475; H03F 2200/129

(57) ABSTRACT

An amplifier circuit includes an amplifier configured to produce two output voltages based on two input voltages; a first capacitor and a second capacitor each coupled to inputs of the amplifier; and a calibration circuit configured, while operating in a calibration mode, to cause each of the two output voltages to equal a reference voltage and to concurrently charge the first capacitor and a second capacitor, the first capacitor and the second capacitor each coupled to a first input of the amplifier and a second input of the amplifier, respectively.

### STATEMENT OF GOVERNMENT INTEREST

This invention was made with government support under contract FA8650-23-C-7304 with the Department of Defense. The government has certain rights in the invention.

### FIELD OF DISCLOSURE

The present disclosure relates to electronic circuitry, and more particularly, to techniques for simultaneous common-mode and differential mode offset compensation in analog circuits.

### BACKGROUND

Integrated circuits have active devices that are fabricated at increasingly smaller scales. As a result, the performance of such circuits is susceptible to process accuracy, temperature, and other factors. For example, a given chip can deviate from design parameters by 50% or more. For on-chip high gain differential amplifiers, such deviations can result in large voltage offsets in both common-mode and differential mode. These offsets can bias the circuits to the point of substantial non-compliance with a given specification or failure to function as designed. Therefore, non-trivial issues are present with existing integrated circuit designs.

### BRIEF DESCRIPTION OF THE DRAWINGS

FIG. 1 is a block diagram of a system including a load and an amplifier/buffer, in accordance with an example of the present disclosure.

FIG. 2 is a schematic diagram of the amplifier/buffer of FIG. 1 with a calibration circuit, in accordance with an example of the present disclosure.

FIGS. 3A and 3B are schematic diagrams of the calibration circuit of FIG. 2, in accordance with an example of the present disclosure.

FIGS. 4A and 4B are schematic diagrams of the calibration circuit of FIG. 2, in accordance with another example of the present disclosure.

FIG. 5 is a flow diagram of an example method of compensating for a bias voltage of an amplifier, in accordance with an example of the present disclosure.

Although the following detailed description refers to illustrative examples, many alternatives, modifications, and variations thereof will be apparent in light of this disclosure.

### DETAILED DESCRIPTION

An amplifier circuit includes an amplifier configured to produce an output signal based on an input signal, capacitors in series with a differential input, and a calibration circuit. The amplifier may have a bias such that the output signal is offset from the intended output by some amount of voltage. To correct for or otherwise offset this bias, with the differential amplifier input set to zero during calibration, the calibration circuit compares both output voltages of the amplifier to a reference voltage (Vref) and adjusts both of the input voltages (IN_P and IN_N) to the amplifier to cause both of the output voltages (OUT_P and OUT_N) of the amplifier to equal Vref, while concurrently charging the capacitors. After calibration, the calibration circuit is disabled, and the capacitors remain charged so as to leave the output voltages (OUT_P and OUT_N) both equal to reference voltage (Vref). Numerous variations will be apparent in light of this disclosure.

Active devices within an integrated circuit (IC) control the flow of electric current. An example of such an active device is an amplifier, although the principles discussed herein also apply to other analog devices. Active devices, such as operational amplifiers, are susceptible to variations in the manufacturing process of the semiconductor chip, and other factors such as temperature. These variations can cause a given device to have different “zero points” or voltage offsets from the intended design. For example, the output voltage of a given device can deviate from design specifications up to 50%, or more in some cases. Furthermore, variations from chip to chip (or wafer to wafer, as the case may be) can lead to significant inconsistencies in the performance of otherwise identical chips. Large offsets both in common-mode and differential mode of active devices within an IC can cause significant biases, which may be corrected (or offset) to bring operational parameters into alignment with design specifications. In some cases, however, the biases are large enough to disable or otherwise prevent the chip from functioning (that is, the biases cannot be sufficiently offset for the chip to become operational). For example, an operational amplifier (op-amp) uses an input offset voltage to cause the output voltage to be zero. Each op-amp may require a different input offset voltage to account for variations in the manufacturing process, operational temperature, and other factors.

To this end, examples of the present disclosure provide techniques for simultaneous common-mode and differential mode offset calibration by adjusting the input offset voltage using capacitors that are charged by a calibration circuit. After such simultaneous common-mode and differential mode offset calibration had been performed, the relevant circuitry can shut off and consume little to no power.

### Amplifier/Buffer

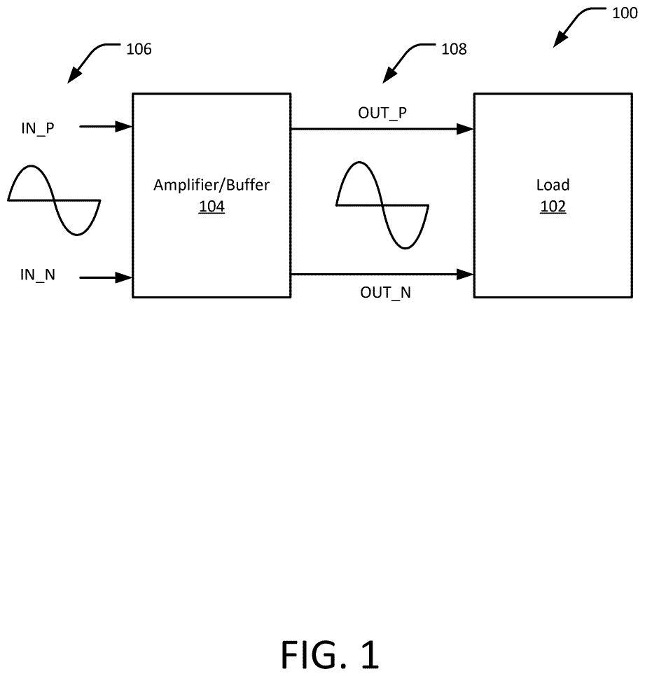

FIG. 1 is a block diagram of a system 100 including a load 102 and an amplifier/buffer 104, in accordance with an example of the present disclosure. In some examples, the system 100 is part of an integrated circuit, such as a CMOS-based integrated circuit. The load 102 can include devices that store and/or consume energy for applications such as imaging, radar, and radio communications, particularly in small form factors such as integrated circuits. The amplifier/buffer 104 includes an amplifier and additional circuitry, such as described in further detail below. A differential output 108 of the amplifier/buffer 104 (OUT_P and OUT_N) is based on a differential input signal 106 (IN_P and IN_N). For example, for a given differential input signal 106, the amplifier/buffer 104 produces an amplified version of the differential input signal 106 as the differential output signal 108. However, the amplifier/buffer 104 may have a bias on the differential output signal 108. For instance, the differential output signal 108 may be 10-20 millivolts higher or lower than zero while the differential input signal 106 is zero, where the differential output signal 108 is otherwise expected to be zero.

In accordance with an example of the present disclosure, capacitors coupled to the differential input of the amplifier/buffer 104 can provide a constant or near-constant voltage to effectively cancel out the bias on the output of the amplifier/buffer 104. For example, during calibration, the capacitors can be charged to a voltage that results in an added output offset of the amplifier/buffer 104, effected by appropriate amplifier input voltages, to cancel out both common-mode offsets and differential mode biases. For example, the amplifier output with zero input may have a +10 mV bias offset on the output due to a process mismatch on the amplifier/buffer chip. In this case, an added −10 mV output offset, effected by appropriate amplifier input voltages, will cancel out the process induced +10 mV offset on the output. This is achieved by switching a calibration circuit into the amplifier circuit and adjusting the input voltages of the amplifier to cause the output voltages of the amplifier circuit to equal a reference voltage while the amplifier/buffer 104 is at DC (e.g., with zero input signal feeding the capacitors that feed the input of the amplifier/buffer 104).

During calibration, the capacitors are charged to a voltage that causes the output voltages of the amplifier/buffer 104 to remain at the reference voltage while the amplifier/buffer 104 is at DC after calibration. For improved operation, inputs to the amplifier should have high impedance (low leakage) so that the capacitors maintain their charge for as long as possible. For example, the gate of a field-effect transistor (FET) has very high impedance. Thus, a capacitor coupled to a FET will maintain a voltage when the FET is turned off.

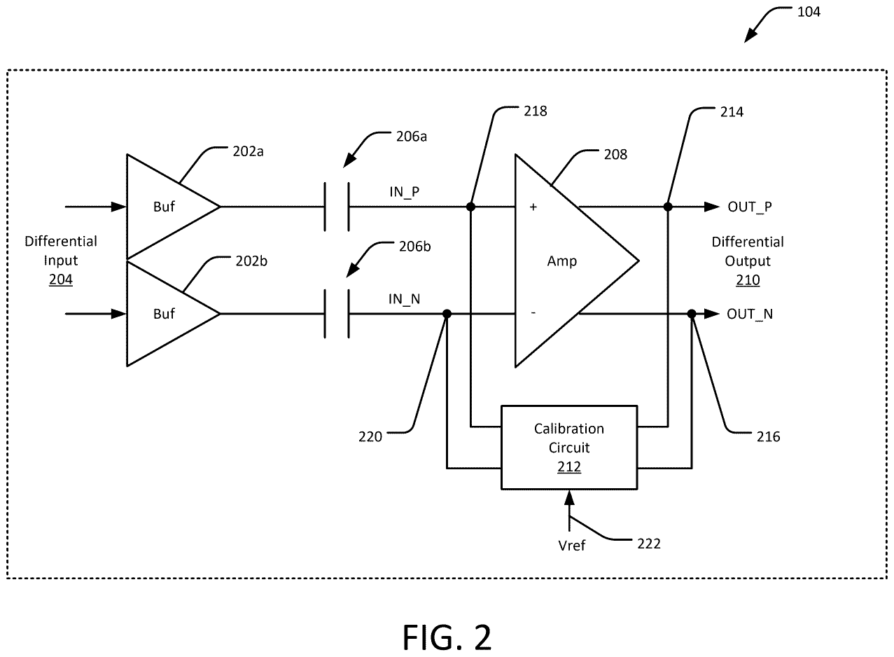

FIG. 2 is a schematic diagram of the amplifier/buffer 104 of FIG. 1, in accordance with an example of the present disclosure. The amplifier/buffer 104 includes two buffers 202a, 202b for receiving a differential input 204, a first capacitor 206a, a second capacitor 206b, and an amplifier 208 for amplifying the differential input 204 to produce a differential output 210. Note that, in some examples, the buffers 202a, 202b are not needed if the differential input 204 comes from a low impedance source (e.g., less than approximately 8 ohms). The differential input 204 feeding the capacitors 206a and 206b can be, for example, the input signal 106 of FIG. 1 zero (no signal). The first capacitor 206a is in series between the buffer 202a and a non-inverting input (IN_P) of the amplifier 208. The second capacitor 206b is in series between the buffer 202b and an inverting input (IN_N) of the amplifier 208.

The amplifier/buffer 104 further includes a calibration circuit 212 having a first terminal 214 and a second terminal 216 each coupled to the non-inverting (OUT_P) and inverting (OUT_N) outputs of the amplifier 208, respectively, a third terminal 218 and a fourth terminal 220 each coupled to the non-inverting (IN_P) and inverting (IN_N) inputs of the amplifier 208, respectively, and a fifth terminal 222 configured to receive a voltage source Vref.

In operation, the calibration circuit 212 calibrates the amplifier/buffer 104 to compensate for any offset at the differential output 210. As will be discussed in further detail below, the calibration circuit 212 can be switched into the amplifier/buffer 104 during calibration and switched out of the amplifier/buffer 104 after calibration is complete. During calibration, the calibration circuit 212 individually compares each differential output 210 of the amplifier 208 to Vref while the differential input 204 is zero. The calibration circuit then adjusts input voltages IN_P and IN_N based on the comparison to cause both of the output voltages OUT_P and OUT_N to equal Vref, while concurrently charging capacitors 206a and 206b. After calibration, the calibration circuit 212 is disabled, and the first and second capacitors 206a, 206b remain charged so as to leave the output voltages OUT_P and OUT_N both equal to Vref. In the calibration circuits described below, the output side refers to the outputs of the amplifier 208 and the input side refers to the inputs of the amplifier 208.

### Calibration Circuit-Common-Mode In Phase

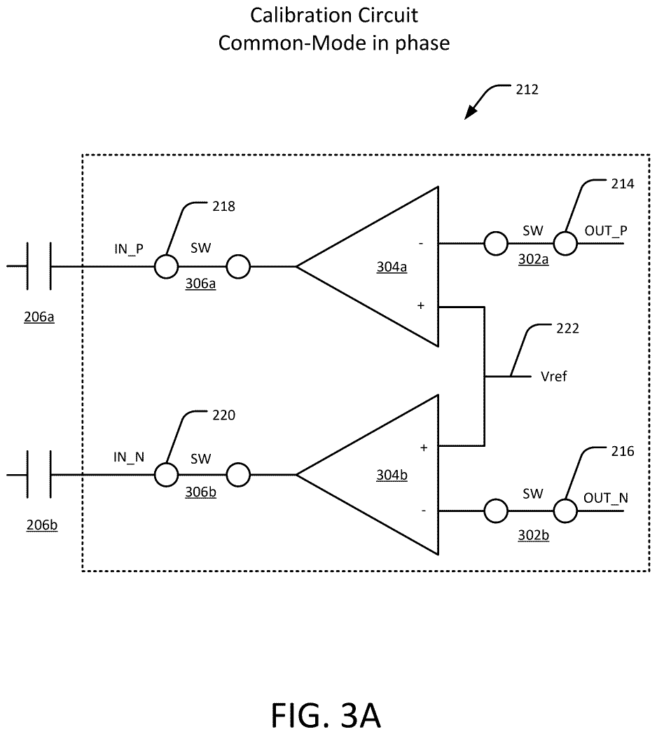

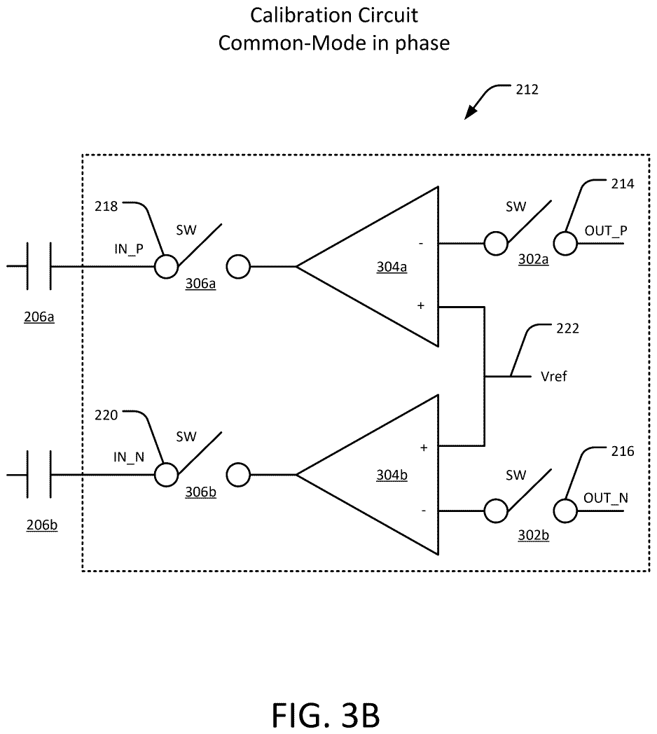

FIGS. 3A and 3B are schematic diagrams of the calibration circuit 212 of FIG. 2, in accordance with an example of the present disclosure. In FIGS. 3A and 3B, the calibration circuit 212 is configured for common-mode in phase operation. The calibration circuit 212 includes a first output side switch 302a, a second output side switch 302b, a first calibration amplifier 304a, a second calibration amplifier 304b, a first input side switch 306a, and a second input side switch 306b. In some examples, the first output side switch 302a, the second output side switch 302b, the first input side switch 306a, and the second input side switch 306b can be controlled by a logic controller or logic circuit integrated into the calibration circuit 212 or the amplifier/buffer 104. In some examples, the first calibration amplifier 304a and the second calibration amplifier 304b are each op-amps.

The first output side switch 302a is coupled in series between an inverting input of the first calibration amplifier 304a and the non-inverting output (OUT_P) of the amplifier 208 of FIG. 2 via the first terminal 214. A non-inverting input of the first calibration amplifier 304a is coupled to Vref. The second output side switch 302b is coupled in series between an inverting input of the second calibration amplifier 304b and the inverting output (OUT_N) of the amplifier 208 via the second terminal 216. A non-inverting input of the second calibration amplifier 304b is coupled to Vref.

The first input side switch 306a is coupled in series between an output of the first calibration amplifier 304a and the first capacitor 206a via the third terminal 218. The second input side switch 306b is coupled in series between an output of the second calibration amplifier 304b and the second capacitor 206b via the fourth terminal 220.

FIG. 3A shows the configuration of the first and second output side switches 302a, 302b and the first and second input side switches 306a, 306b during calibration. During calibration, the first and second output side switches 302a and 302b are closed, and the first and second input side switches 306a and 306b are closed. The differential input 204 is zero during calibration. This permits the first calibration amplifier 304a to compare the non-inverting output (OUT_P) of the amplifier 208 (with any bias) to Vref, and permits the second calibration amplifier 304b to simultaneously compare the inverting output (OUT_N) of the amplifier 208 (with any bias) also to Vref. The calibration amplifiers 304a and 304b changes the input voltages IN_P and IN_N to cause the output voltages OUT_P and OUT_N to both equal Vref. In the process, capacitors 206a and 206b are both charged to voltages that maintain the output voltage while the calibration amplifiers 304a and 304b are switched off and the differential input 204 is zero.

FIG. 3B shows the configuration of the first and second output side switches 302a, 302b, and the first and second input side switches 306a, 306b, after calibration. After calibration, the first and second output side switches 302a and 302b are open, and the first and second input side switches 306a and 306b are open. This removes the first and second calibration amplifiers 304a and 304b from the remainder of the amplifier/buffer 104 circuit. To conserve energy, power can be removed from the first and second calibration amplifiers 304a and 304b while the output side switches 302a, 302b and the input side switches 306a, 306b are open.

### Calibration Circuit-Common-Mode Out of Phase

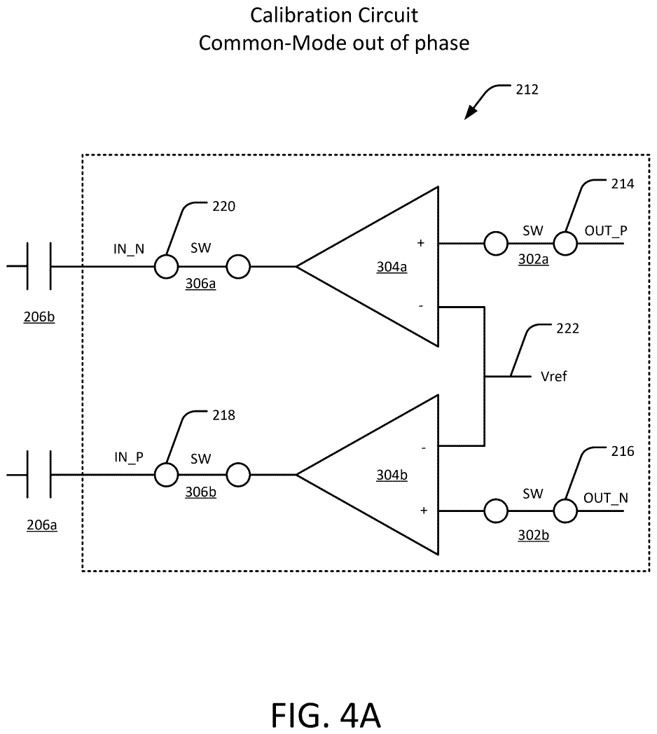

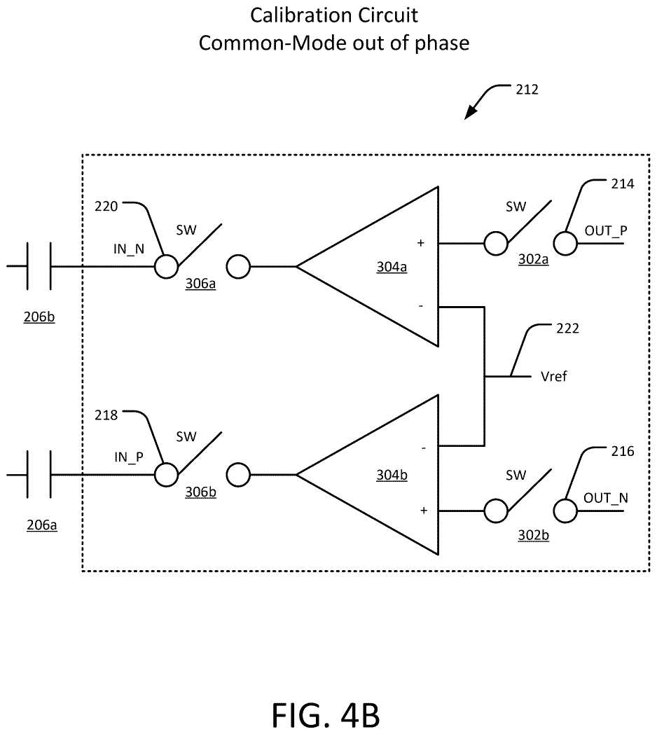

FIGS. 4A and 4B are schematic diagrams of the calibration circuit 212 of FIG. 2, in accordance with another example of the present disclosure. In FIGS. 4A and 4B, the calibration circuit 212 is configured for common-mode out of phase operation. The calibration circuit 212 includes the first output side switch 302a, the second output side switch 302b, the first calibration amplifier 304a, the second calibration amplifier 304b, the first input side switch 306a, and the second input side switch 306b.

The first output side switch 302a is coupled in series between the non-inverting input of the first calibration amplifier 304a and the non-inverting output (OUT_P) of the amplifier 208 of FIG. 2 via the first terminal 214. The inverting input of the first calibration amplifier 304a is coupled to Vref. The second output side switch 302b is coupled in series between the non-inverting input of the second calibration amplifier 304b and the inverting output (OUT_N) of the amplifier 208 via the second input terminal 216. The inverting input of the second calibration amplifier 304b is coupled to Vref.

The first input side switch 306a is coupled in series between the output of the first calibration amplifier 304a and the second capacitor 206b via the fourth terminal 220. The second input side switch 306b is coupled in series between the output of the second calibration amplifier 304b and the first capacitor 206a via the third terminal 218.

FIG. 4A shows the configuration of the first and second output side switches 302a, 302b and the first and second input side switches 306a, 306b during calibration. During calibration, the first and second output side switches 302a and 302b are closed, and the first and second input side switches 306a and 306b are closed. This permits the first calibration amplifier 304a to compare the non-inverting output (OUT_P) of the amplifier 208 to Vref, and permits the second calibration amplifier 304b to simultaneously compare the inverting output (OUT_N) of the amplifier 208 also to Vref. The calibration amplifiers 304a and 304b changes the input voltages IN_P and IN_N to cause the output voltages OUT_P and OUT_N to both equal Vref. In the process, capacitors 306a and 306b are both charged to voltages that maintain the output voltage while the calibration amplifiers 304a and 304b are switched off and the input is zero.

FIG. 4B shows the configuration of the first and second output side switches 302a, 302b, and the first and second input side switches 306a, 306b, after calibration. After calibration, the first and second output side switches 302a and 302b are open, and the first and second input side switches 306a and 306b are open. This removes the first and second calibration amplifiers 304a and 304b from the remainder of the amplifier/buffer 104 circuit. To conserve energy, power can be removed from the first and second calibration amplifiers 304a and 304b while the output side switches 302a, 302b and the input side switches 306a, 306b are open.

### Example Amplifier/Buffer Calibration Methodology

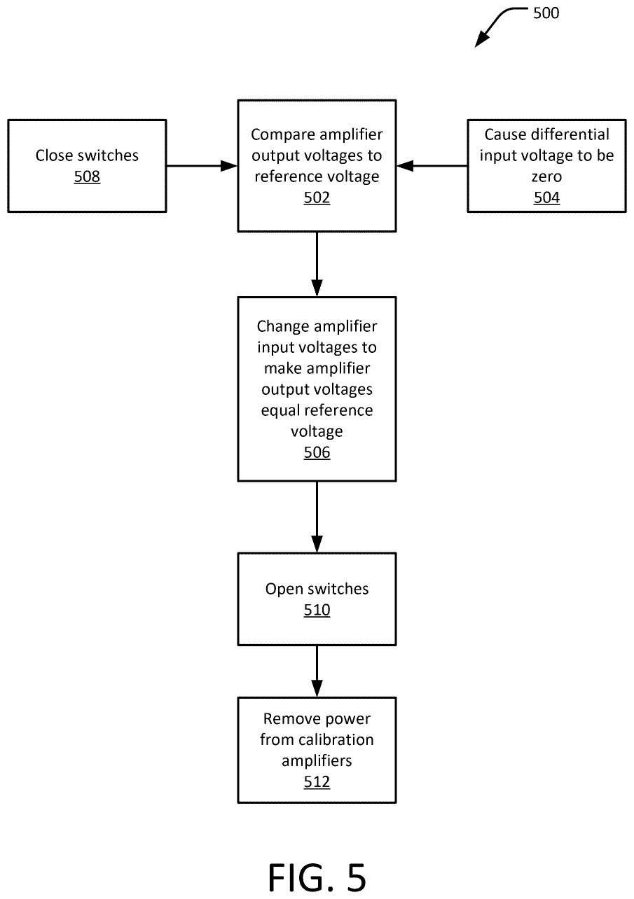

FIG. 5 is a flow diagram of an example method 500 of compensating for a bias voltage of an amplifier, in accordance with an example of the present disclosure. The method 500 can be implemented using, for example, the amplifier/buffer 104 of FIG. 1. The amplifier has two output voltages, OUT_P and OUT_N, and the calibration circuit has two inputs and two outputs, fed back to the amplifier IN_P and IN_N (to which capacitors 206a and 206b are also connected), such as shown in FIG. 2. The selection of which calibration amplifier within the calibration circuit depends upon the amplifier common-mode being in or out of phase.

The method 500 includes simultaneously comparing 502, while operating in a calibration mode, each of the output voltages OUT_P and OUT_N of the amplifier to a reference voltage Vref to obtain two voltage differences between the output voltages and the reference voltage. For example, the output voltage OUT_P of the amplifier is compared to the reference voltage Vref using the first calibration amplifier 304a and the output voltage OUT_N of the amplifier is also compared to the reference voltage Vref using the second calibration amplifier 304b. This creates the two voltage differences: OUT_P-Vref and OUT_N-Vref. The method 500 further includes causing 504 the differential input 204 to be zero while operating in calibration mode and while comparing 502 the output voltages OUT_P and OUT_N of the amplifier to the reference voltage Vref.

The method 500 further includes causing 506, while operating in the calibration mode, the amplifier output voltages OUT_P and OUT_N to equal the reference voltage Vref by changing the amplifier input voltages IN_P and IN_N via the calibration amplifiers 304a and 304b. For example, the amplifier outputs, OUT_P and OUT_N, are fed to the calibration amplifiers 304a and 304b, which produce two voltage differences, OUT_P-Vref and OUT_N -Vref. These are error signals used by the calibration amplifiers 304a and 304b in a feedback loop that includes the amplifier 208. If in calibration mode with OUT_P or OUT_N≠Vref, the system is in a dynamic, transitory state that cannot be assigned any specific relationship to capacitor voltages from which to draw any conclusions until OUT_P=OUT_N=Vref. However, when the closed loop has settled (if the in-phase/out-of-phase common mode selection is correct), the outputs OUT_P and OUT_N of the amplifier 208 should both equal Vref, at which point capacitors 206a and 206b have been charged to the proper voltages to keep OUT_P and OUT_N equaling Vref with zero input and the calibration circuitry turned off.

In some examples, the amplifier is coupled via switches, while operating in the calibration mode, to a calibration circuit having a first calibration amplifier and a second calibration amplifier, where the comparing 502 of the output voltages of the amplifier to the reference voltage is performed by the first calibration amplifier (e.g., the calibration amplifier 304a) and the second calibration amplifier (e.g., the calibration amplifier 304b).

In some examples, the calibration circuit includes a first output side switch (e.g., switch 302a) coupled in series between a first output of the amplifier (OUT_P) and the first calibration amplifier, a second output side switch (e.g., switch 302b) coupled in series between a second output of the amplifier (OUT_N) and the second calibration amplifier, a first input side switch (e.g., switch 306a) coupled in series between the first calibration amplifier and the first capacitor, and a second input side switch (e.g., switch 306b) coupled in series between the second calibration amplifier and the second capacitor, such as described with respect to FIGS. 3A, 3B, 4A and 4B. In these examples, the method 500 further includes closing 508 the first output side switch, the second output side switch, the first input side switch, and the second input side switch while the calibration circuit is operating in the calibration mode. In these examples, the method 500 further includes opening 510 the first output side switch, the second output side switch, the first input side switch, and the second input side switch while the calibration circuit is not operating in the calibration mode. In some examples, the method 500 further includes causing 512, while not operating in the calibration mode, power to be removed from the first calibration amplifier and the second calibration amplifier. In some examples, the calibration is performed once subsequent to powering on the amplifier/buffer 104. However, the calibration can be performed at any time, for example, periodically or upon the occurrence of certain conditions, such as a loss of power, an undervoltage or overvoltage condition, a loss of the load 102 or other anomaly, or other condition in which the offset voltage is insufficient for operation of the load 102.

Unless specifically stated otherwise, it will be appreciated that terms such as “processing,” “computing,” “calculating,” and “determining” refer to the action and/or process of a computer or computing system, or similar electronic computing device, that manipulates and/or transforms data represented as physical quantities (for example, electronic) within the registers and/or memory units of the computer system into other data similarly represented as physical entities within the registers, memory units, or other such information storage transmission or displays of the computer system.

The terms “circuit” or “circuitry” can include, for example, hardwired circuitry, programmable circuitry, such as computer processors comprising one or more individual instruction processing cores, state machine circuitry, and/or firmware that stores instructions executed by programmable circuitry. The circuitry can include a processor and/or controller configured to execute one or more instructions to perform one or more operations described herein. The instructions can be implemented as, for example, an application, software, firmware, etc., configured to cause the circuit or circuitry to perform any of the operations or functions described herein. Software can be implemented as a software package, code, instructions, instruction sets and/or data recorded on a computer-readable storage device. Software can be implemented to include any number of processes, and processes, in turn, can be implemented to include any number of threads, etc., in a hierarchical fashion. Firmware can be implemented as code, instructions or instruction sets and/or data that are hard-coded (e.g., nonvolatile) in memory devices. The circuit or circuitry can be implemented as part of a larger system, for example, an integrated circuit (IC), an application-specific integrated circuit (ASIC), a system-on-a-chip (SoC), desktop computers, laptop computers, tablet computers, servers, smartphones, etc. Other examples can be implemented as software executed by a programmable control device. In such cases, the terms “circuit” or “circuitry” are intended to include a combination of software and hardware such as a programmable control device or a processor capable of executing the software. As described herein, various examples can be implemented using hardware elements, software elements, or any combination thereof. Examples of hardware elements can include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, and/or chip sets.

Some embodiments can be described using the expression “coupled” and “connected” along with their derivatives. These terms are not intended as synonyms for each other. For example, some embodiments can be described using the terms “connected” and/or “coupled” to indicate that two or more elements are in direct physical or electrical contact with each other. The term “coupled,” however, can also mean that two or more elements are not in direct contact with each other, but yet still cooperate or interact with each other.

### FURTHER EXAMPLES

The following examples pertain to further examples, from which numerous permutations and configurations will be apparent.

Example 1 provides an amplifier circuit comprising an amplifier having a first input and a second input each configured to receive an input signal, and a first output and a second output each configured to produce an output signal based on the input signal; a first capacitor coupled to the first input of the amplifier; a second capacitor coupled to the second input of the amplifier; and a calibration circuit having a first terminal coupled to the first input of the amplifier, a second terminal coupled to the second input of the amplifier, a third terminal coupled to the first output of the amplifier, a fourth terminal coupled to the second output of the amplifier, and a fifth terminal configured to receive a reference voltage.

Example 2 includes the subject matter of Example 1, wherein the first input of the amplifier is a non-inverting input; and the second input of the amplifier is an inverting input.

Example 3 includes the subject matter of Examples 1 or 2, wherein the calibration circuit includes a first calibration amplifier having a first input, a second input, and an output, the first input of the first calibration amplifier coupled to the fifth terminal configured to receive the reference voltage, the second input of the first calibration amplifier coupled to the first terminal via a first output side switch, the output of the first calibration amplifier coupled to the third terminal via a first input side switch; and a second calibration amplifier having a first input, a second input, and an output, the first input of the second calibration amplifier coupled to the fifth terminal configured to receive the reference voltage, the second input of the second calibration amplifier coupled to the second terminal via a second output side switch, the output of the second calibration amplifier coupled to the fourth terminal via a second input side switch.

Example 4 includes the subject matter of Example 3, wherein the first input side switch is coupled in series between the third terminal and the first capacitor; and the second input side switch is coupled in series between the fourth terminal and the second capacitor.

Example 5 includes the subject matter of Examples 3 or 4, wherein the first input of the first calibration amplifier is a non-inverting input; the second input of the first calibration amplifier is an inverting input; the first input of the second calibration amplifier is a non-inverting input; and the second input of the second calibration amplifier is an inverting input.

Example 6 includes the subject matter of any one of Examples 3-5, wherein the first input side switch is coupled in series between the fourth terminal and the second capacitor; and the second input side switch is coupled in series between the third terminal and the first capacitor.

Example 7 includes the subject matter of Example 6, wherein the first input of the first calibration amplifier is an inverting input; the second input of the first calibration amplifier is a non-inverting input; the first input of the second calibration amplifier is an inverting input; and the second input of the second calibration amplifier is a non-inverting input.

Example 8 provides a method of compensating for a bias voltage of an amplifier, the method comprising comparing, while operating in a calibration mode, each of two output voltages of the amplifier to a reference voltage to obtain voltage differences between each of the output voltages and the reference voltage; and causing, while operating in the calibration mode, each of two input voltages to the amplifier to change such that each of the two output voltages of the amplifier equal the reference voltage.

Example 9 includes the subject matter of Example 8, wherein the amplifier is coupled, while operating in the calibration mode, to a calibration circuit having a first calibration amplifier and a second calibration amplifier; and the comparing of each of the two output voltages of the amplifier to the reference voltage is performed by the first calibration amplifier and the second calibration amplifier, respectively.

Example 10 includes the subject matter of Example 9, wherein the calibration circuit includes a first output side switch coupled in series between a first output of the amplifier and the first calibration amplifier, a second output side switch coupled in series between a second output of the amplifier and the second calibration amplifier, a first input side switch coupled in series between the first calibration amplifier and a first capacitor, and a second input side switch coupled in series between the second calibration amplifier and a second capacitor, and wherein the method further comprises closing the first output side switch, the second output side switch, the first input side switch, and the second input side switch while the calibration circuit is operating in the calibration mode.

Example 11 includes the subject matter of Example 10, further comprising opening the first output side switch, the second output side switch, the first input side switch, and the second input side switch while the calibration circuit is not operating in the calibration mode.

Example 12 includes the subject matter of any one of Examples 9-11, further comprising causing, while not operating in the calibration mode, power to be removed from the first calibration amplifier and the second calibration amplifier.

Example 13 includes the subject matter of any one of Examples 8-12, further comprising causing, while operating in the calibration mode, an input voltage of the amplifier to be zero.

Example 14 provides an amplifier circuit comprising an amplifier configured to produce two output voltages based on two input voltages; a first capacitor and a second capacitor each coupled to inputs of the amplifier; and a calibration circuit configured, while operating in a calibration mode, to cause each of the two output voltages to equal a reference voltage and to concurrently charge the first capacitor and a second capacitor, the first capacitor and the second capacitor each coupled to a first input of the amplifier and a second input of the amplifier, respectively.

Example 15 includes the subject matter of Example 14, wherein the first input of the amplifier is a non-inverting input; and the second input of the amplifier is an inverting input.

Example 16 includes the subject matter of Examples 14 or 15, wherein the calibration circuit includes a first calibration amplifier having a first input, a second input, and an output, the first input of the first calibration amplifier configured to receive the output signal produced by the amplifier via a first output side switch, the second input of the first calibration amplifier configured to receive a reference voltage, the output of the first calibration amplifier configured to provide the charge to the first capacitor via a first input side switch; and a second calibration amplifier having a first input, a second input, and an output, the first input of the second calibration amplifier configured to receive the output signal produced by the amplifier via a second output side switch, the second input of the second calibration amplifier configured to receive a reference voltage, the output of the second calibration amplifier configured to provide the charge to the second capacitor via a second input side switch.

Example 17 includes the subject matter of Example 16, wherein the first input side switch is coupled in series between the first calibration amplifier and the first capacitor; and the second input side switch is coupled in series between the second calibration amplifier and the second capacitor.

Example 18 includes the subject matter of Example 17, wherein the first input of the first calibration amplifier is a non-inverting input; the second input of the first calibration amplifier is an inverting input; the first input of the second calibration amplifier is a non-inverting input; and the second input of the second calibration amplifier is an inverting input.

Example 19 includes the subject matter of any one of Examples 16-18, wherein the first input side switch is coupled in series between the first calibration amplifier and the second capacitor; and the second input side switch is coupled in series between the second calibration amplifier and the first capacitor.

Example 20 includes the subject matter of Example 19, wherein the first input of the first calibration amplifier is an inverting input; the second input of the first calibration amplifier is a non-inverting input; the first input of the second calibration amplifier is an inverting input; and the second input of the second calibration amplifier is a non-inverting input.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. An amplifier circuit comprising:
an amplifier having a first input and a second input each configured to receive an input signal, and a first output and a second output each configured to produce an output signal based on the input signal;
a first capacitor coupled to the first input of the amplifier;
a second capacitor coupled to the second input of the amplifier; and
a calibration circuit having a first terminal coupled to the first input of the amplifier, a second terminal coupled to the second input of the amplifier, a third terminal coupled to the first output of the amplifier, a fourth terminal coupled to the second output of the amplifier, and a fifth terminal configured to receive a reference voltage.

2. The amplifier circuit of claim 1, wherein
the first input of the amplifier is a non-inverting input; and
the second input of the amplifier is an inverting input.

3. The amplifier circuit of claim 1, wherein the calibration circuit includes
a first calibration amplifier having a first input, a second input, and an output, the first input of the first calibration amplifier coupled to the fifth terminal configured to receive the reference voltage, the second input of the first calibration amplifier coupled to the first terminal via a first output side switch, the output of the first calibration amplifier coupled to the third terminal via a first input side switch; and
a second calibration amplifier having a first input, a second input, and an output, the first input of the second calibration amplifier coupled to the fifth terminal configured to receive the reference voltage, the second input of the second calibration amplifier coupled to the second terminal via a second output side switch, the output of the second calibration amplifier coupled to the fourth terminal via a second input side switch.

4. The amplifier circuit of claim 3, wherein
the first input side switch is coupled in series between the third terminal and the first capacitor; and
the second input side switch is coupled in series between the fourth terminal and the second capacitor.

5. The amplifier circuit of claim 3, wherein
the first input of the first calibration amplifier is a non-inverting input;
the second input of the first calibration amplifier is an inverting input;
the first input of the second calibration amplifier is a non-inverting input; and
the second input of the second calibration amplifier is an inverting input.

6. The amplifier circuit of claim 3, wherein
the first input side switch is coupled in series between the fourth terminal and the second capacitor; and
the second input side switch is coupled in series between the third terminal and the first capacitor.

7. The amplifier circuit of claim 6, wherein:
the first input of the first calibration amplifier is an inverting input;
the second input of the first calibration amplifier is a non-inverting input;
the first input of the second calibration amplifier is an inverting input; and
the second input of the second calibration amplifier is a non-inverting input.

8. A method of compensating for a bias voltage of an amplifier, the method comprising:
comparing, while operating in a calibration mode, each of two output voltages of the amplifier to a reference voltage to obtain voltage differences between each of the output voltages and the reference voltage; and
causing, while operating in the calibration mode, each of two input voltages to the amplifier to change such that each of the two output voltages of the amplifier equal the reference voltage.

9. The method of claim 8, wherein
the amplifier is coupled, while operating in the calibration mode, to a calibration circuit having a first calibration amplifier and a second calibration amplifier; and
the comparing of each of the two output voltages of the amplifier to the reference voltage is performed by the first calibration amplifier and the second calibration amplifier, respectively.

10. The method of claim 9, wherein the calibration circuit includes a first output side switch coupled in series between a first output of the amplifier and the first calibration amplifier, a second output side switch coupled in series between a second output of the amplifier and the second calibration amplifier, a first input side switch coupled in series between the first calibration amplifier and a first capacitor, and a second input side switch coupled in series between the second calibration amplifier and a second capacitor, and wherein the method further comprises closing the first output side switch, the second output side switch, the first input side switch, and the second input side switch while the calibration circuit is operating in the calibration mode.

11. The method of claim 10, further comprising opening the first output side switch, the second output side switch, the first input side switch, and the second input side switch while the calibration circuit is not operating in the calibration mode.

12. The method of claim 9, further comprising causing, while not operating in the calibration mode, power to be removed from the first calibration amplifier and the second calibration amplifier.

13. The method of claim 8, further comprising causing, while operating in the calibration mode, an input voltage of the amplifier to be zero.

14. An amplifier circuit comprising:
an amplifier configured to produce two output voltages based on two input voltages;
a first capacitor and a second capacitor each coupled to inputs of the amplifier; and
a calibration circuit configured, while operating in a calibration mode, to cause each of the two output voltages to equal a reference voltage and to concurrently charge the first capacitor and a second capacitor, the first capacitor and the second capacitor each coupled to a first input of the amplifier and a second input of the amplifier, respectively.

15. The amplifier circuit of claim 14, wherein
the first input of the amplifier is a non-inverting input; and
the second input of the amplifier is an inverting input.

16. The amplifier circuit of claim 14, wherein the calibration circuit includes
a first calibration amplifier having a first input, a second input, and an output, the first input of the first calibration amplifier configured to receive the output signal produced by the amplifier via a first output side switch, the second input of the first calibration amplifier configured to receive a reference voltage, the output of the first calibration amplifier configured to provide the charge to the first capacitor via a first input side switch; and
a second calibration amplifier having a first input, a second input, and an output, the first input of the second calibration amplifier configured to receive the output signal produced by the amplifier via a second output side switch, the second input of the second calibration amplifier configured to receive a reference voltage, the output of the second calibration amplifier configured to provide the charge to the second capacitor via a second input side switch.

17. The amplifier circuit of claim 16, wherein
the first input side switch is coupled in series between the first calibration amplifier and the first capacitor; and
the second input side switch is coupled in series between the second calibration amplifier and the second capacitor.

18. The amplifier circuit of claim 17, wherein
the first input of the first calibration amplifier is a non-inverting input;
the second input of the first calibration amplifier is an inverting input;
the first input of the second calibration amplifier is a non-inverting input; and
the second input of the second calibration amplifier is an inverting input.

19. The amplifier circuit of claim 16, wherein
the first input side switch is coupled in series between the first calibration amplifier and the second capacitor; and
the second input side switch is coupled in series between the second calibration amplifier and the first capacitor.

20. The amplifier circuit of claim 19, wherein:
the first input of the first calibration amplifier is an inverting input;
the second input of the first calibration amplifier is a non-inverting input;
the first input of the second calibration amplifier is an inverting input; and
the second input of the second calibration amplifier is a non-inverting input.
